(19) United States
(12) Patent Application Publication
(10) Pub. No.: US 2009/0128222 A1
(43) Pub. Date: May 21, 2009

(54) APPARATUS AND METHOD FOR ADJUSTING WORKING FREQUENCY OF VRD BY DETECTING TEMPERATURE

(75) Inventors: Li Zeng, Shanghai City (CN); Shih-Hao Liu, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 12/016,427

(22) Filed: Jan. 18, 2008

(30) Foreign Application Priority Data
Nov. 15, 2007 (TW) 96143270

(51) Int. Cl. H01L 35/00; G05F 1/10; H03B 19/00

(52) U.S. Cl. 327/512; 327/113; 327/538

(57) ABSTRACT

The invention provides an apparatus for adjusting a working frequency of a VRD by detecting temperature. The apparatus includes a temperature control module, a load module and a controller. The temperature control module is used for detecting a temperature of a CPU, and judging an output load state of the VRD according to the detected temperature of the CPU, so as to output a control signal according the output load state. The load module is connected to the VRD, and is used for providing an external resistance to the VRD. The controller is respectively coupled to the load module and the temperature control module, and is used for receiving the control signal and adjusting a resistance of the load module according to the received control signal, so as to adjust a working frequency of the VRD. A power consumption of the VRD may be reduced based on the present invention.

### CROSS-REFERENCE TO RELATED APPLICATION

This application claims the priority benefit of Taiwan application serial no. 96143270, filed on Nov. 15, 2007. The entirety of the above-mentioned patent application is hereby incorporated by reference herein and made a part of this specification.

### BACKGROUND OF THE INVENTION

1. Field of the Invention

The present invention relates to an apparatus for adjusting a working frequency of a voltage regulator down (VRD) and a method thereof. More particularly, the present invention relates to an apparatus for adjusting a working frequency of a VRD by detecting temperature and a method thereof, by which power consumption of the VRD may be reduced.

2. Description of Related Art

A present electronic product generally has a relatively high requirement on power supply thereof, and a supply voltage is usually required to be transformed into a relatively high output voltage or a relatively low output voltage for being provided to the electronic product. A voltage regulator down (VRD) is presently used as a basic voltage adjusting circuit in a general power supply. The VRD may output a voltage lower than a corresponding input voltage, and may stabilize the output voltage. The VRD is generally used for supplying a voltage to a CPU in a general server or a common personal computer.

The VRD generally fixes the supply voltage to a relatively stable supply voltage via a switch with a fixed switching frequency. However, the switch with the fixed switching frequency is generally applied to the VRD module of the computer, by which regardless of the CPU being lightly loaded or heavily loaded, the VRD maintains a relatively high working power, and therefore if the CPU is lightly loaded, a part of the working power of the VRD is wasted, which may cause a wastage of energy.

Taiwan patent No. TW-1223741 discloses a power reduction system including a processor which may adjust the supply voltage, and at least a temperature sensor coupled to the processor for sensing a temperature of the processor. The temperature sensor adjusts the supply voltage of the processor to an acceptable low supply voltage according to the temperature of the processor and a clock frequency sensed by the processor. The power reduction system further includes a flash memory for storing the acceptable low supply voltages of a plurality of the processors. At least a part of the supply voltages is adjusted according to the clock frequency sensed by the processor and the sensed temperature of the processor.

According to the system disclosed by the Taiwan patent No. TW-1223741, the temperature sensor is used for sensing the temperature of the processor which may adjust the supply voltage thereof, and the supply voltage of the processor is adjusted to the acceptable low supply voltage according to the sensed temperature of the processor and the clock frequency sensed by the processor.

Though such system may adjust the supply voltage of the processor to a low supply voltage when the processor is lightly loaded, it is still similar to an existing technique that a problem of excessive power consumption of the VRD used for supplying power to the CPU is still not solved.

### SUMMARY OF THE INVENTION

The present invention is directed to an apparatus for adjusting a working frequency of a VRD by detecting temperature, by which excessive power consumption of the VRD is avoided.

The present invention is directed to a method for adjusting a working frequency of a VRD by detecting temperature, by which a working frequency of a VRD is decreased when a CPU is lightly loaded, or the working frequency of the VRD is increased when the CPU is heavily loaded.

The present invention provides an apparatus for adjusting a working frequency of a VRD by detecting temperature. The apparatus includes a temperature control module, a load module and a controller. The temperature control module is used for detecting a temperature of a CPU, and judging an output load state of the VRD according to the detected temperature of the CPU, so as to output a control signal according the output load state. The load module is connected to the VRD, and is used for providing an external resistance to the VRD. The controller is respectively coupled to the load module and the temperature control module, and is used for receiving the control signal and adjusting a resistance of the load module according to the received control signal, so as to adjust a working frequency of the VRD.

According to an embodiment of the present invention, the temperature control module includes a temperature measuring instrument and a baseboard management controller module. The temperature measuring instrument is used for detecting an actual temperature of the CPU. The baseboard management controller module is used for comparing the actual temperature of the CPU to a predetermined temperature threshold value, and if the temperature of the CPU is less than the threshold value, the baseboard management controller module may send a control signal for decreasing the working frequency of the VRD. The load module includes a first oscillation resistor and a second oscillation resistor. The controller is a switching device coupled to the first oscillation resistor in series, and the second oscillation resistor is coupled to the first oscillation resistor and the switching device in parallel. The switching device is a transistor having a first source/drain, a second source/drain and a gate. The first source/drain is coupled to the first oscillation resistor, the second source/drain is coupled to a ground voltage, and the gate is coupled to the temperature control module for receiving the control signal, and turning the transistor on/off according to the control signal. The working frequency of the VRD has a predetermined ration with a resistance of an external resistor formed by the first oscillation resistor and the second oscillation resistor. The resistance of the external resistor is the resistance of the second oscillation resistor, or the resistance formed when the first oscillation resistor is connected to the second oscillation resistor in parallel.

The present invention provides another apparatus for adjusting a working frequency of a VRD by detecting temperature. The apparatus includes a temperature control module and an adjustable resistance module. The temperature control module is used for detecting the temperature of a CPU, and judging an output load state of the VRD according the temperature of the CPU, so as to output a control signal according the output load state. The adjustable resistance module is coupled to the VRD and the temperature control module, and is used for adjusting the resistance of the adjustable resistance module according to the control signal, so as to adjust the working frequency of the VRD.

According to an embodiment of the present invention, the adjustable resistance module is a potentiometer.

The present invention provides a method for adjusting a working frequency of a VRD by detecting temperature. The method may be described as follows. First, a load module coupled to a VRD is provided. Next, a temperature of a CPU is detected. Next, a load state of the CPU is judged according the temperature of the CPU. Finally, a resistance of the load module is adjusted according to the load state of the CPU, so as to adjust the working frequency of the VRD.

The present invention provides an apparatus for adjusting a working frequency of a VRD by detecting temperature, by which the load state of the CPU may be judged by detecting the temperature of the CPU, such that the working frequency of the VRD may be adjusted according to the load state of the CPU, and power consumption of the VRD may be controlled, and accordingly waste of energy is avoided.

In order to make the aforementioned and other objects, features and advantages of the present invention comprehensible, an embodiment accompanied with figures is described in detail below.

### BRIEF DESCRIPTION OF THE DRAWINGS

FIG. 1 is a structural diagram of an apparatus for adjusting a working frequency of a VRD by detecting temperature according to an embodiment of the present invention.

FIG. 2 is a structural diagram of an apparatus for adjusting a working frequency of a VRD by detecting temperature according to another embodiment of the present invention.

FIG. 3 is a diagram illustrating a relation between external resistances and working frequencies of a VRD.

FIG. 4 is a structural diagram of an apparatus for adjusting a working frequency of a VRD by detecting temperature according to another embodiment of the present invention.

FIG. 5 is a flowchart illustrating a method for adjusting a working frequency of a VRD by detecting temperature according to another embodiment of the present invention.

### DESCRIPTION OF EMBODIMENTS

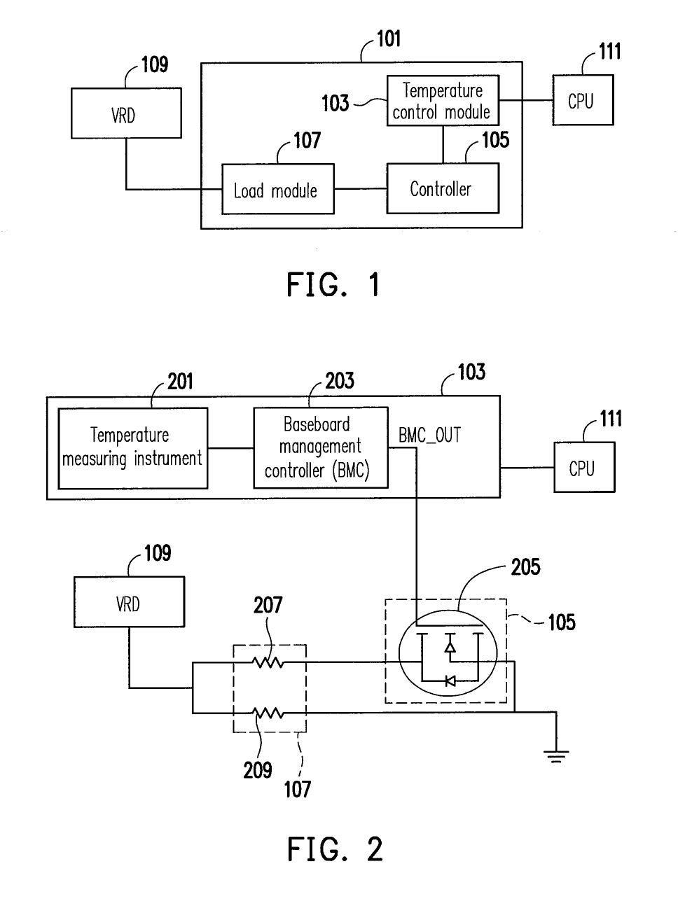

FIG. 1 is a structural diagram of an apparatus for adjusting a working frequency of a VRD by detecting temperature according to an embodiment of the present invention.

The apparatus 101 for adjusting a working frequency of a VRD by detecting temperature includes a temperature control module 103, a load module 107 and a controller 105. The temperature control module 103 is used for detecting a temperature of a CPU 111, and judging an output load state of a VRD 109 according a present temperature of the CPU 111, so as to output a control signal according the output load state. The load module 107 is coupled to the VRD 109, and is used for providing an external resistance to the VRD 109. The controller 105 is respectively coupled to the load module 107 and the temperature control module 103, and is used for receiving the control signal and adjusting a resistance of the load module 107 according to the received control signal, so as to adjust a working frequency of the VRD 109.

In a multi-phase, synchronous rectification, and voltage decreasing type CPU power supply circuit, switching depletion of the VRD, diode depletion within a switching device, and driving of transistors are all proportional to the working frequency (the working frequency influences a dissipation power of the VRD). Therefore, as long as the working frequency is under control, depletion of the VRD may be controlled. When the CPU is heavily loaded, the temperature thereof is relatively high, and the required working frequency of the VRD is relatively high accordingly; when the CPU is lightly loaded, the temperature thereof is relatively low, and the required working frequency of the VRD is relatively low accordingly. In the present embodiment, the output load state of the VRD 109 may be judged by detecting the temperature of the CPU 111 when a core voltage of the CPU 111 is satisfied, and the working frequency of the VRD 109 used for supplying power for the CPU 111 is adjusted according to the output load state, such that the VRD 109 may work under a relatively low working frequency when the CPU 111 is lightly loaded, so as to reduce a power consumption.

FIG. 2 is a structural diagram of an apparatus for adjusting a working frequency of a VRD by detecting temperature according to another embodiment of the present invention.

The apparatus for adjusting a working frequency of a VRD by detecting temperature includes the temperature control module 103, the load module 107 and the controller 105. The temperature control module 103 is used for detecting the temperature of the CPU 111, and judging the output load state of the VRD 109 according the temperature of the CPU 111, so as to output the control signal according the output load state. The temperature control module 103 includes a temperature measuring instrument 201 and a baseboard management controller (BMC) module 203. The temperature measuring instrument 201 is used for detecting a present temperature of the CPU 111, and the temperature measuring instrument 201 may be a thermal resistor, a thermocouple and semiconductor temperature sensor etc., and may also be an onboard temperature measurement device of the CPU 111, such as an erect ball-shape or a strip-shape thermal resistor under a socket of the CPU 111. The BMC module 203 is used for comparing the temperature of the CPU 111 to a predetermined temperature threshold value, so as to determine the load state of the CPU 111, and output a control signal BMC_OUT according to the load state for adjusting the working frequency of the VRD 109. The BMC module 203 may be a built-in program of an operating system of the CPU 111. By programming, if the threshold value is set to 50° C., when the temperature of the CPU 111 is less than 50° C., the CPU 111 is judged to be lightly loaded, and when the temperature of the CPU 111 is greater than 50° C., the CPU 111 is judged to be heavily loaded. The controller 105 is respectively coupled to the VRD 109 and the temperature control module 103 for receiving the control signal and adjusting a resistance of an external resistor, so as to adjust the working frequency of the VRD 109. The load module 107 is coupled to the VRD 109 for providing the external resistor for the VRD 109, and the load module 107 includes a first oscillation resistor 207 and a second oscillation resistor 209. The controller 105 is a transistor 205 coupled in series to the first oscillation resistor 207. The second oscillation resistor 209 is coupled to the first oscillation resistor 207 and the transistor 205 in parallel. The transistor 205 includes a first source/drain, a second source/drain and a gate. The first source/drain is coupled to the first oscillation resistor 207, the second source/drain is coupled to a ground voltage, and the gate is coupled to the temperature control module 103 for receiving the control signal BMC_OUT, and turning the transistor on/off according to the control signal.

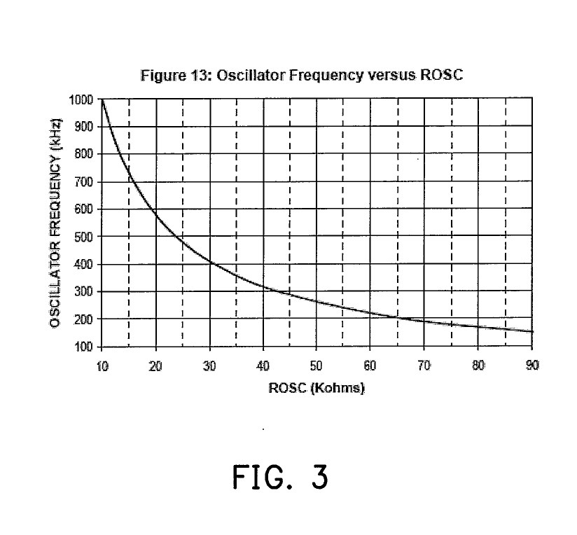

FIG. 3 is a diagram illustrating a relationship between external resistances and working frequencies of a VRD. As shown in FIG. 3, when the resistance of the external resistor of the VRD increases, the working frequency thereof drops; and when the resistance of the external resistor of the VRD decreases, the working frequency thereof increases. The working frequency is proportional to the depletion of the VRD, and therefore the depletion of the VRD may be controlled by adjusting the resistance of the external resistor of the VRD. In the embodiment shown in FIG. 2, the second oscillation resistor 209 functions as the external resistor of the VRD when the transistor 205 is turned off. The transistor 205 controls whether or not to connect the first oscillation resistor 207 and the second oscillation resistor 209 in parallel to function as the external resistor of the VRD according to the control signal BMC_OUT sent from the BMC module 201. The working frequency of the VRD has a predetermined relation with the resistance of the external resistor formed by the first oscillation resistor 207 and the second oscillation resistor 209. When the CPU is heavily loaded, the transistor 205 is turned on, and the resistance of the external resistor of the VRD is a resistance formed by parallel connection of the first oscillation resistor 207 and the second oscillation resistor 209. When the CPU is lightly loaded, the transistor 205 is turned off, and the resistance of the external resistor of the VRD is the resistance of the second oscillation resistor 209. Since the resistance of the second oscillation resistor 209 is greater than the resistance formed by parallel connection of the first oscillation resistor 207 and the second oscillation resistor 209, the working frequency of lightly loaded CPU is less than that of heavily loaded CPU, and therefore depletion of the CPU may be reduced when the CPU is lightly loaded.

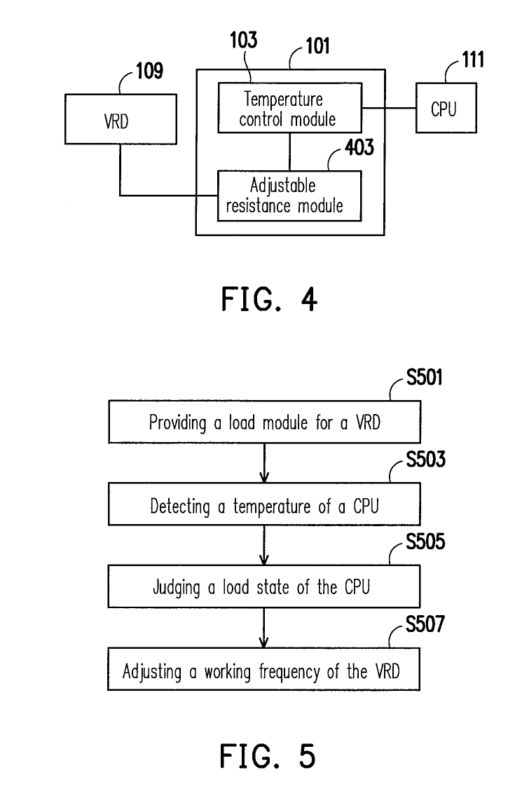

FIG. 4 is a structural diagram of an apparatus for adjusting a working frequency of a VRD by detecting temperature according to another embodiment of the present invention.

The apparatus 401 for adjusting a working frequency of a VRD by detecting temperature of the present embodiment includes the temperature control module 103 and an adjustable resistance module 403. The temperature control module 103 is used for detecting the temperature of the CPU 111, and judging the output load state of the VRD 109 according the detected temperature of the CPU 111, so as to output the control signal according the output load state. Function of the temperature control module 103 is the same to that of the temperature control module 103 of the embodiment shown in FIG. 2. The adjustable resistance module 403 is coupled to the VRD 109 and the temperature control module 103, and is used for adjusting the resistance of the adjustable resistance module 403 according to the control signal, so as to adjust the working frequency of the VRD 109. The adjustable resistance module 403 may be a potentiometer.

Moreover, as to the VRD, selection of an output inductor capacitor thereof relates to the working frequency of the VRD, and therefore when the working frequency corresponding to the lightly loaded CPU is about to be set, the threshold value of the working frequency when the same inductor capacitor is applied should be noted, and a voltage ripple thereof should meet the demand of a core voltage of the CPU.

FIG. 5 is a flowchart illustrating a method for adjusting a working frequency of a VRD by detecting temperature according to another embodiment of the present invention.

In step S501, an external resistance is provided for a VRD.

In step S503, a temperature of a CPU is detected. Temperature measurement device such as a thermal resistor, a thermocouple and semiconductor temperature sensor etc. may be used for detecting the temperature of the CPU, and an onboard temperature measurement device of the CPU such as an erect ball-shape or strip-shape thermal resistor under a socket of the CPU etc. may also be applied for detecting the temperature of the CPU.

In step S505, a load state of the CPU is judged. When the CPU is heavily loaded, the temperature thereof is higher, and when the CPU is lightly loaded, the temperature thereof is lower. Therefore, the detected temperature of the CPU may be compared to a predetermined temperature threshold value, so as to determine the load sate of the CPU. For example, the temperature threshold value is set to 50° C., when the temperature of the CPU is less than 50° C., the CPU is considered to be lightly loaded, and when the temperature of the CPU is greater than 50° C., the CPU is considered to be heavily loaded.

In step S507, a working frequency of the VRD is adjusted. As shown in FIG. 3, when the resistance of the external resistor of the VRD is increased, the working frequency of the VRD decreases, and when the resistance of the external resistor of the VRD is decreased, the working frequency of the VRD increases. The working frequency of the VRD is proportional to the depletion of the VRD, and therefore the depletion of the VRD may be controlled by adjusting the resistance of the external resistor of the VRD. When the CPU is heavily loaded, the CPU requires a higher power, and now the VRD requires a relatively greater working frequency, and therefore the external resistance of the VRD is required to be reduced. When the CPU is lightly loaded, the CPU requires a lower power, and now the VRD only requires a relatively lower working frequency for satisfying a required power of the CPU, and therefore the external resistance of the VRD is required to be increased, so as to reduce the working frequency of the VRD, and accordingly the depletion of the VRD is reduced since the working frequency of the VRD is proportional to the depletion of the VRD.

Adjustment of the resistance of the external resistor of the VRD may be achieved by changing a connection of the external resistor. For example, the first oscillation resistor may be connected to the second oscillation resistor in parallel to reduce the resistance of the external resistor, and the first oscillation resistor may be connected in series to a switching device such as a transistor. When the CPU is heavily loaded, a path where the first oscillation resistor is located is turned on for increasing the working frequency of the VRD. When the CPU is lightly loaded, the path where the first oscillation resistor is located is turned off for decreasing the working frequency of the VRD, so as to reduce the depletion of the VRD and avoid waste of energy.

In summary, the apparatus for adjusting a working frequency of a VRD by detecting temperature according to the present invention may adjust the working frequency of the VRD based on the load state of the CPU via setting the external resistor of the VRD, such that the VRD may have a relatively low working frequency when the CPU is lightly loaded, and the depletion of the VRD may be reduced accordingly. Moreover, the temperature of the CPU may be detected by the BMC function of the operating system or the onboard temperature sensor of the CPU, and therefore the structure of the apparatus is simple, and operation thereof is convenient.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An apparatus for adjusting a working frequency of a voltage regulator down (VRD) by detecting temperature, comprising:
a temperature control module, for detecting a temperature of a central processing unit (CPU), and judging an output load state of the VRD according the temperature of the CPU, so as to output a control signal according the output load state;
a load module, coupled to the VRD, for providing an external resistance to the VRD; and
a controller, respectively coupled to the load module and the temperature control module, for receiving the control signal and adjusting a resistance of the load module according to the received control signal, so as to adjust a working frequency of the VRD.

2. The apparatus for adjusting a working frequency of a VRD by detecting temperature as claimed in claim 1, wherein the temperature control module comprises:
a temperature measuring instrument, for measuring a present temperature of the CPU; and
a baseboard management controller module, for comparing the present temperature of the CPU to a predetermined temperature threshold value, wherein if the present temperature of the CPU is less than the temperature threshold value, the baseboard management controller module sends the control signal for decreasing the working frequency of the VRD.

3. The apparatus for adjusting a working frequency of a VRD by detecting temperature as claimed in claim 1, wherein the load module comprises a first oscillation resistor and a second oscillation resistor, the controller is a switching device connected to the first oscillation resistor in series, and the second oscillation resistor is connected to the first oscillation resistor and the switching device in parallel.

4. The apparatus for adjusting a working frequency of a VRD by detecting temperature as claimed in claim 3, wherein the switching device is a transistor comprising a first source/drain, a second source/drain and a gate, the first source/drain is coupled to the first oscillation resistor, the second source/drain is coupled to a ground level, and the gate is coupled to the temperature control module for receiving the control signal and turning on/off the transistor according to the control signal.

5. The apparatus for adjusting a working frequency of a VRD by detecting temperature as claimed in claim 3, wherein the working frequency of the VRD has a predetermined relation with a resistance of the external resistor formed by the first oscillation resistor and the second oscillation resistor.

6. The apparatus for adjusting a working frequency of a VRD by detecting temperature as claimed in claim 5, wherein the resistance of the external resistor is a resistance of the second oscillation resistor or a resistance formed when the first oscillation resistor and the second oscillation resistor are connected in parallel.

7. An apparatus for adjusting a working frequency of a VRD by detecting temperature, comprising:
a temperature control module, for detecting a temperature of a CPU, and judging an output load state of the VRD according the temperature of the CPU, so as to output a control signal according the output load state; and
an adjustable resistance module, coupled to the VRD and the temperature control module, for adjusting a resistance of the adjustable resistance module according to the control signal, so as to adjust a working frequency of the VRD.

8. The apparatus for adjusting a working frequency of a VRD by detecting temperature as claimed in claim 7, wherein the adjustable resistance module is a potentiometer.

9. The apparatus for adjusting a working frequency of a VRD by detecting temperature as claimed in claim 7, wherein the temperature control module comprises:
a temperature measuring instrument, for measuring a present temperature of the CPU; and
a baseboard management controller module, for comparing the present temperature of the CPU to a predetermined temperature threshold value, wherein if the present temperature of the CPU is less than the temperature threshold value, the baseboard management controller module sends the control signal for decreasing the working frequency of the VRD.

10. A method for adjusting a working frequency of a VRD by detecting temperature, comprising:
providing a load module coupled to a VRD;
detecting a temperature of a CPU;
judging an output load state of the VRD according to a detected temperature of the CPU; and
adjusting a resistance of the load module according to the output load state of the CPU, so as to adjust a working frequency of the VRD.

11. The method for adjusting a working frequency of a VRD by detecting temperature as claimed in claim 10, wherein the load module comprises a first oscillation resistor and a second oscillation resistor coupled in parallel and connected to the VRD, wherein adjusting the resistance of the load module comprises:
providing a switching device connected in series to the first oscillation resistor; and
turning on/of the switching device according to the output load state of the VRD.

12. The method for adjusting a working frequency of a VRD by detecting temperature as claimed in claim 11 further comprising:
comparing the temperature of the CPU to a predetermined temperature threshold value;
sending a control signal for decreasing the working frequency of the VRD if the temperature of the CPU is less than the temperature threshold value; and
turning off the switching device after the control signal is received.
